(19) United States
(12) Patent Application Publication
(10) Pub. No.: US 2026/0182183 A1
(43) Pub. Date: Jun. 25, 2026

(54) DISPLAY DEVICE AND METHOD OF MANUFACTURING THE DISPLAY DEVICE

(71) Applicant: Samsung Display Co., LTD., Yongin-si (KR)

(72) Inventors: JUNGI KIM, Yongin-si (KR); JIN-LAK KIM, Yongin-si (KR); HYE SUN KIM, Yongin-si (KR); BOGEON JEON, Yongin-si (KR)

(21) Appl. No.: 19/384,122

(22) Filed: Nov. 10, 2025

(30) Foreign Application Priority Data
Dec. 20, 2024 (KR) 10-2024-0193287

(51) Int. Cl. H10K 59/131; H10K 59/12; H10K 59/122; H10K 59/123

(52) U.S. Cl. CPC H10K 59/131; H10K 59/1201; H10K 59/122; H10K 59/123

(57) ABSTRACT

A display device according to an embodiment of the present disclosure may include a substrate, a circuit layer, a first insulating layer, a first conductive layer, a second insulating layer, and a first pixel electrode. The circuit layer may be disposed on the substrate. The first insulating layer may be disposed on the circuit layer. The first conductive pattern may be disposed on the first insulating layer. The second insulating layer may be disposed on the first insulating layer and expose an upper surface of the first conductive pattern. The first pixel electrode may be disposed on the second insulating layer. The upper surface of the first conductive pattern may be in full-surface contact with the first pixel electrode. The upper surface of the first conductive pattern and an upper surface of the second insulating layer may be disposed on the same plane.

This application claims priority to Korean Patent Application No. 10-2024-0193287, filed on December 20, 2024, and all the benefits accruing therefrom under 35 U.S.C. §119, the content of which in its entirety is herein incorporated by reference.

### BACKGROUND

### FIELD

The present disclosure herein relates to a display device and a method of manufacturing the display device, and more specifically, to a display device having an improved display quality and a method of manufacturing the display device.

### DESCRIPTION OF THE RELATED ART

A display device may be a flat panel display device, such as, for example, a liquid crystal display device, a field emission display device, and a light-emitting display panel. A light-emitting display device may include an organic light-emitting display device containing an organic light-emitting diode as a light-emitting element.

In some cases, the display device may include a substrate, a plurality of circuit layers, a plurality of insulating layers, and a plurality of electrodes. A contact hole may generally be used to electrically connect the plurality of layers. The contact hole refers to a small hole that connects metal wires of a semiconductor

circuit or other materials in a process of manufacturing the display device. As more pixels are integrated, a size of the contact hole decreases, and a process for manufacturing the contact hole with relatively high precision may be desired. In an example in which the contact hole is not properly formed, the contact hole may cause a short-circuit or an excessive current flow to degrade reliability of the display device.

Techniques for integrating pixels while maintaining the reliability of the display device are desired.

### SUMMARY

The present disclosure provides a display device with improved reliability and optical characteristics due in part to a conductive pattern which is brought into full-surface contact with a pixel electrode.

The present disclosure also provides a method for manufacturing a display device with improved reliability and optical characteristics by bringing a conductive pattern into full-surface contact with a pixel electrode.

A display device according to an embodiment of the present disclosure may include a substrate, a circuit layer, a first insulating layer, a first conductive pattern, a second insulating layer, and a first pixel electrode. The circuit layer may be disposed on the substrate. The first insulating layer may be disposed on the circuit layer. The first conductive pattern may be disposed on the first insulating layer. The second insulating layer may be disposed on the first insulating layer and expose an upper surface of the first conductive pattern. The first pixel electrode may be disposed on the second insulating layer. The upper surface of the first conductive pattern may be in full-surface contact with the first pixel electrode. The upper surface of the first conductive pattern and an upper surface of the second insulating layer may be disposed on the same plane.

In an embodiment, the display device may further include a second conductive pattern disposed on the first insulating layer. A distance between the substrate and the first conductive pattern may be greater than a distance between the substrate and the second conductive pattern.

In an embodiment, the second insulating layer may cover the second conductive pattern. The upper surface of the second insulating layer may be flat.

In an embodiment, the first insulating layer may include a first insulating layer region and a second insulating layer region. The first insulating layer region may have a flat upper surface, and the first conductive pattern may be disposed on the first insulating layer region. The second insulating layer region may have a flat upper surface, and the second conductive pattern may be disposed on the second insulating layer region. The first insulating layer region may have a thickness greater than a thickness of the second insulating layer region.

In an embodiment, the circuit layer may include a third insulating layer and a third conductive pattern. The third insulating layer may be disposed below the first insulating layer. The third conductive pattern may be disposed between the first insulating layer and the third insulating layer. The third conductive pattern may overlap the first conductive pattern. The first insulating layer may have a substantially uniform thickness.

In an embodiment, the circuit layer may include a third insulating layer. The third insulating layer may be disposed below the first insulating layer. A contact hole that overlaps the second conductive pattern may be defined in the third insulating layer. The first insulating layer may have a substantially uniform thickness.

In an embodiment, the display device may further include a second conductive pattern disposed on the first insulating layer. The first conductive pattern may have a thickness greater than a thickness of the second conductive pattern. The second insulating layer may cover the second conductive pattern. The upper surface of the second insulating layer may be flat.

In an embodiment, the number of layers of the first conductive pattern may be greater than the number of layers of the second conductive pattern.

In an embodiment, the display device may further include a pixel defining layer which is disposed on the second insulating layer and the first pixel electrode and in which a first pixel opening which exposes a portion of the first pixel electrode is defined. The first pixel opening may overlap the first conductive pattern on a plane.

In an embodiment, the first pixel electrode may have a symmetrical shape with respect to a virtual line passing through a center of the first pixel electrode on the plane.

In an embodiment, the display device may further include a second pixel electrode and a second conductive pattern. The second pixel electrode may be spaced apart from the first pixel electrode. The second conductive pattern may be disposed on the first insulating layer and connected to the second pixel electrode through a contact hole defined in the second insulating layer.

In an embodiment, a distance between the substrate and the first conductive pattern may be greater than a distance between the substrate and the second conductive pattern.

In an embodiment, the display device may further include a pixel defining layer which is disposed on the second insulating layer, the first pixel electrode, and the second pixel electrode and in which a first pixel opening which exposes a portion of the first pixel electrode and a second pixel opening which exposes a portion of the second pixel electrode are defined. The first pixel opening may overlap the first conductive pattern on a plane. The second pixel opening may overlap the second conductive pattern on a plane.

In an embodiment, the first pixel electrode may have a symmetrical shape with respect to a virtual line passing through a center of the first pixel electrode on the plane. The second pixel electrode may have a symmetrical shape with respect to a virtual line passing through a center of the second pixel electrode on the plane.

A method for manufacturing a display device according to the present disclosure may include: forming a substrate; forming a circuit layer on the substrate; forming a first insulating layer on the circuit layer; forming a conductive layer, wherein the forming of the conductive layer forms a first conductive pattern on the first insulating layer; forming a second preliminary insulating layer on the first insulating layer, wherein the second preliminary insulating layer covers the first conductive pattern; forming a second insulating layer by polishing the second preliminary insulating layer, wherein the second insulating layer exposes an entire upper surface of the first conductive pattern; and forming a first pixel electrode on the first conductive pattern and the second insulating layer, wherein the first pixel electrode is in full-surface contact with the upper surface of the first conductive pattern.

In an embodiment, the forming of the conductive layer may form a second conductive pattern spaced apart from the first conductive pattern.

The forming of the first insulating layer may include: forming a first preliminary insulating layer on the circuit layer; and patterning the first preliminary insulating layer by using a halftone mask.

The first insulating layer may include a first insulating layer region that overlaps the first conductive pattern and has a flat upper surface and a second insulating layer region that overlaps the second conductive pattern and has a flat upper surface, and the first insulating layer region may have a thickness greater than a thickness of the second insulating layer region.

A display device according to an embodiment of the present disclosure may include a substrate, a first transistor, a first pixel electrode, and a pixel defining layer.

The first transistor may be disposed on the substrate.

The first pixel electrode may be connected to the first transistor.

The pixel defining layer may be disposed on the first transistor and the first pixel electrode, and a first pixel opening which exposes a portion of the first pixel electrode is defined in the pixel defining layer.

The first pixel electrode may have a symmetrical shape with respect to a virtual line passing through a center of the first pixel electrode on a plane.

In an embodiment, the first pixel opening may overlap the first conductive pattern.

In an embodiment, the display device may further include a second transistor and a second pixel electrode. The second transistor may be disposed on the substrate and spaced apart from the first transistor. The second pixel electrode may be connected to the second transistor.

The second pixel opening which exposes a portion of the second pixel electrode may be defined in the pixel defining layer.

The second pixel electrode may not have an asymmetrical shape with respect to a virtual line passing through a center of the second pixel electrode on the plane.

A display device according to the present disclosure includes a substrate, a circuit layer, a first insulating layer, a first conductive pattern, a second insulating layer, and a first pixel electrode.

The circuit layer may be disposed on the substrate.

The first insulating layer may be disposed on the circuit layer.

The first conductive pattern may be disposed on the first insulating layer.

The second insulating layer may be disposed on the first insulating layer and expose an upper surface of the first conductive pattern.

### The first pixel electrode may be disposed on the second insulating layer

The upper surface of the first conductive pattern may be in full-surface contact with the first pixel electrode, and the upper surface of the first conductive pattern and an upper surface of the second insulating layer may be disposed on the same plane.

In an embodiment, the electronic device may further include: a processor configured to control the display device; a memory in which data for operating the display device or the processor are stored; and a power conversion module configured to generate or supply power.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a block diagram illustrating an electronic device according to an embodiment;

FIG. 2 is schematic view illustrating electronic devices according to various embodiments;

FIG. 3 is a schematic plan view illustrating a display device according to an embodiment of the present disclosure;

FIG. 4 is a schematic cross-sectional view illustrating the display device of FIG. 1;

FIG. 5 is an enlarged plan view illustrating region AA of FIG. 3;

FIG. 6 is a cross-sectional view taken along line I-I' of FIG. 5 and illustrating the display device according to an embodiment of the present disclosure;

FIG. 7 is a plan view illustrating a first pixel electrode of FIG. 5;

FIG. 8 is a cross-sectional view illustrating the display device according to an embodiment of the present disclosure;

FIG. 9 is a cross-sectional view illustrating the display device according to an embodiment of the present disclosure;

FIG. 10 is a cross-sectional view illustrating the display device according to an embodiment of the present disclosure;

FIG. 11 is a plan view illustrating the display device according to an embodiment of the present disclosure;

FIG. 12 is a cross-sectional view taken along line I-I' and line II-II' of FIG. 11;

FIG. 13 is a plan view illustrating a second pixel electrode on a plane;

FIG. 14 is a flowchart illustrating a method for manufacturing a display device according to an embodiment of the present disclosure; and

FIGS. 15A to 15G is schematic cross-sectional views illustrating processes of the method for manufacturing the display device according to an embodiment of the present disclosure.

### DETAILED DESCRIPTION

In this specification, it will be understood that when one component (or region, layer, portion) is referred to as being ‘on’, ‘connected to’, or ‘coupled to’ another component, it can be directly disposed/connected/coupled on/to the one component, or an intervening third component may also be present.

Like reference numerals refer to like elements throughout. In the figures, the thickness, ratio, and dimensions of components are exaggerated for clarity of illustration. The term “and/or” includes any and all combinations of one or more of the associated listed items.

It will be understood that although the terms such as ‘first’ and ‘second’ are used herein to describe various elements, these elements should not be limited by these terms. Terms are used to distinguish one component from other components. For example, a first element referred to as a first element in an embodiment can be referred to as a second element in another embodiment without departing from the scope of the appended claims. The terms of a singular form may include plural forms unless referred to the contrary.

Spatially relative terms, such as “below”, “lower”, “above”, and “upper”, may be used herein for ease of description to describe an element and/or a feature's relationship to another element(s) and/or feature(s) as illustrated in the drawings. The terms may be a relative concept and described based on directions expressed in the drawings.

The meaning of ‘include’ or ‘comprise’ specifies a property, a fixed number, a step, an operation, an element, a component or a combination thereof, but does not exclude other properties, fixed numbers, steps, operations, elements, components or combinations thereof.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical and scientific terms) used herein have the same meaning as generally understood by those skilled in the art. Terms as defined in a commonly used dictionary should be construed as having the same meaning as in an associated technical context, and unless defined apparently in the description, the terms are not ideally or excessively construed as having formal meaning.

In this specification, when an embodiment may be implemented differently, the specific process sequence may be performed in an order different from the described sequence. For example, two consecutively described processes may be performed substantially simultaneously, or they may proceed in the reverse order of the described sequence.

A display device according to an embodiment may be applied to various electronic devices. An electronic device according to an embodiment includes the aforementioned display device and may further include modules or devices with additional functionalities other than the display device.

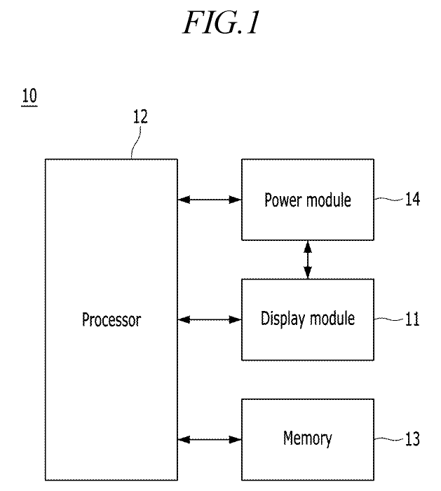

FIG. 1 is a block diagram illustrating an electronic device according to an embodiment. Referring to FIG. 1, an electronic device 10 according to an embodiment may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller.

The memory 15 may store data information for an operation of the processor 12 or the display module 11. In an example in which the processor 12 executes an application stored in the memory 15, an image data signal and/or an input control signal may be transmitted to the display module 11, and the display module 11 may process the received signal to output image information through a display screen.

The power module 14 may include a power supply module, such as, for example, a power adapter or a battery device, and a power conversion module that converts power supplied by the power supply module to generate power for an operation of the electronic device 10.

At least one of the components described herein of the electronic device 10 may be contained in the display device according to the above-described embodiments. In some aspects, some of the individual modules functionally included in a single module may be contained in the display device, and some thereof may be provided separately from the display device. For example, the display device may include the display module 11, and the processor 12, the memory 13, and the power module 14 may be provided in the form of a different device in the electronic device 10 instead of the display device.

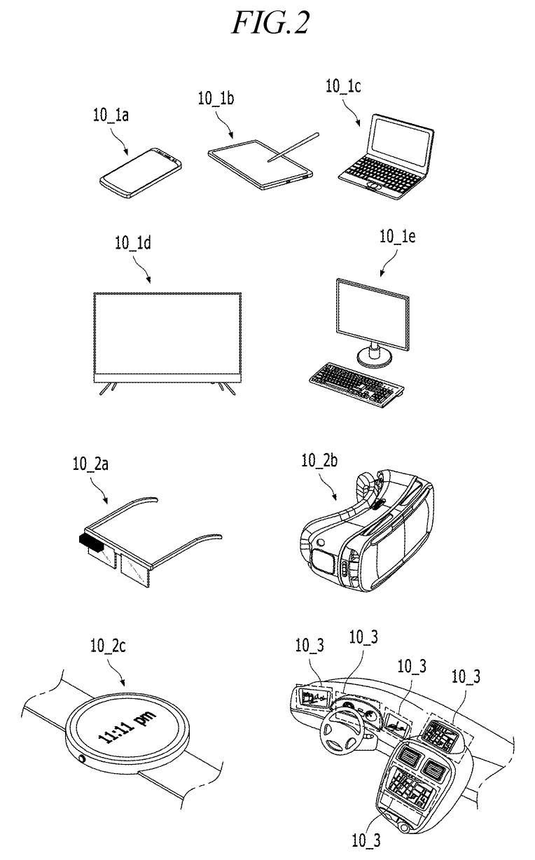

FIG. 2 is schematic view illustrating electronic devices according to various embodiments;

Referring to FIG. 2, various electronic devices to which display devices according to embodiments are applied may include an image display electronic device, such as, for example, a smartphone 10_1a, a tablet PC 10_1b, a laptop computer 10_1c, a TV 10_1d, and a desktop monitor 10_1e, a wearable electronic device including a display module, such as, for example, smart glasses 10_2a, a head-mounted display 10_2b, and a smartwatch 10_2c, and a vehicle electronic device 10_3, such as, for example, an vehicle dashboard, a center fascia, a center information display (CID) disposed on a dashboard, and a room mirror display.

In an embodiment of the present disclosure, a first direction DR1 and a second direction DR2 may be perpendicular to each other. A third direction DR3 may be perpendicular to a plane defined by the first direction DR1 and the second direction DR2.

Hereinafter, embodiments of the present disclosure will be described with reference to the accompanying drawings.

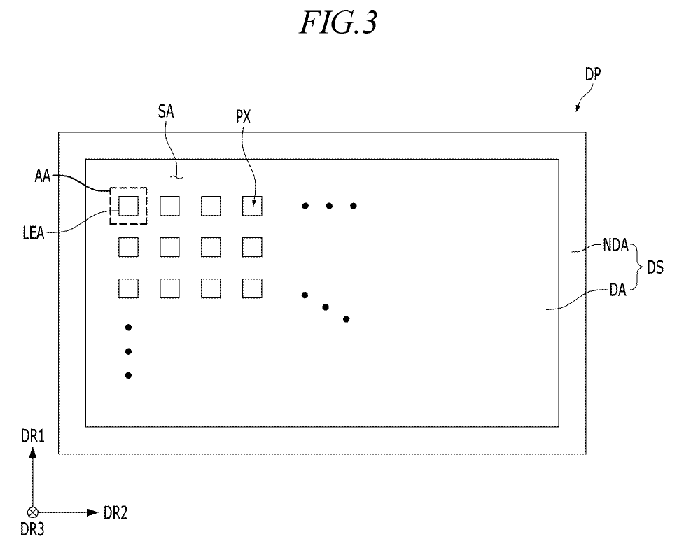

FIG. 3 is a schematic plan view of a display device according to an embodiment of the present disclosure.

Referring to FIG. 3, a display device DP according to an embodiment of the present disclosure may include a display surface DS that provides an image to a user. Although the display surface DS is defined by the first direction DR1 and the second direction DR2 in FIG. 3, embodiments of the present disclosure are not limited thereto. For example, the display surface DS may be defined on a curved surface based on a structural modification (e.g., bending) of the display device DP.

The display surface DS may include a non-display area NDA and a display area DA. The non-display area NDA that does not display an image may surround the display area DA. However, embodiments of the present disclosure are not limited thereto. For example, a shape of each of the non-display area NDA and the display area DA may be modified.

The display area DA may include a light-emitting area LEA and a surrounding area SA.

A plurality of light-emitting areas LEA that are spaced apart from each other may be provided, and a pixel PX may be provided on each of the light-emitting areas LEA.

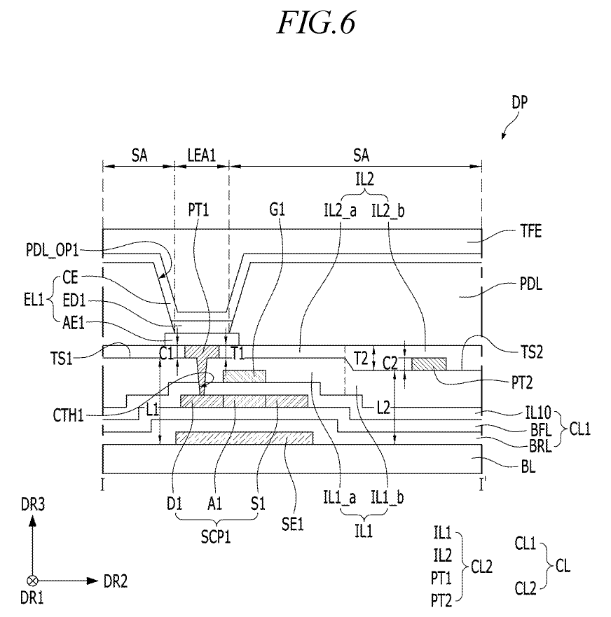

The light-emitting area LEA may be an area through which light emitted from one pixel PX is transmitted. The light-emitting area LEA may be an area that does not block light emitted from a light-emitting diode layer EL1 (refer to FIG. 6) by a pixel defining layer PDL (refer to FIG. 6) which will be described later.

The surrounding area SA may be an area through which light is not transmitted. The surrounding area SA may be an area between the plurality of light-emitting areas LEA. Light may not be transmitted through the surrounding area SA.

Although a plurality of pixels PX are regularly arranged in FIG. 3, the embodiment is not limited to the shape of arrangement of the plurality of pixels PX. For example, the plurality of pixels PX may be arranged in various shapes.

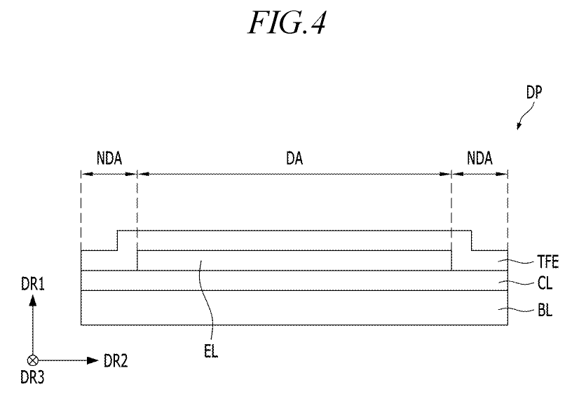

FIG. 4 is a schematic cross-sectional view of the display device DP of FIG. 1.

The display device DP may include a base layer BL, a circuit layer CL, a light-emitting diode layer EL, and a thin film encapsulation TFE.

The base layer BL may be a member that provides a base surface on which the circuit layer CL is disposed.

The base layer BL may include one of polyimide (PI), polyethylene terephthalate (PET), polyethylene naphthalate (PEN), polycarbonate (PC), polyarylate (PAR), polyetherimide (PEI), polyethersulfone (PES), fiber reinforced plastics, metal foil, and thin glass. However, embodiments of the present disclosure are not limited thereto.

The circuit layer CL may be disposed on the base layer BL. The circuit layer CL may include a plurality of insulating layers, a plurality of semiconductor patterns, a plurality of conductive patterns, a plurality of control lines, a plurality of signal lines, a plurality of scan lines, a plurality of data lines, and a plurality of power lines.

The light-emitting diode layer EL may be disposed on the circuit layer CL. The light-emitting diode layer EL may include a light-emitting element. The light-emitting element may include an organic light-emitting material, an inorganic light-emitting material, an organic-inorganic light emitting material, a quantum dot, a quantum rod, a micro-LED, or a nano-LED. The light-emitting diode layer EL may include an anode, a hole functional layer, a light-emitting layer, an electron functional layer, and a counter electrode.

The encapsulation layer TFE may be disposed on the light-emitting diode layer EL. The encapsulation TFE may include at least one inorganic encapsulation film and at least one organic encapsulation film. The inorganic encapsulation film may protect the light-emitting diode layer EL from moisture and oxygen. The organic encapsulation film may protect the light-emitting diode layer EL from foreign substances, such as, for example, dust particles. The inorganic encapsulation film may include a silicon nitride (SiₓNᵧ) layer, a silicon oxynitride (SiOₓNᵧ) layer, a silicon oxide (SiOₓ) layer, a titanium oxide (TiO₂) layer, or an aluminum oxide (Al₂O₃) layer. The organic encapsulation film may include an acrylic-based organic layer. However, embodiments of the present disclosure are not limited thereto.

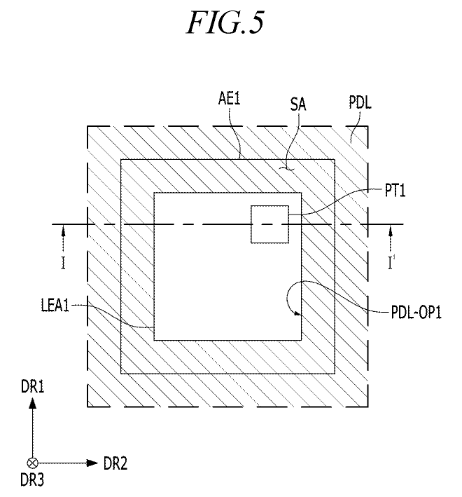

FIG. 5 is an enlarged plan view illustrating region AA of FIG. 3; FIG. 6 is a cross-sectional view taken along line I-I' of FIG. 5 and illustrating the display device DP according to an embodiment of the present disclosure.

Referring to FIGS. 5 and 6, the circuit layer CL of the display device DP according to an embodiment of the present disclosure may include a first circuit layer CL1 and a second circuit layer CL2.

The first circuit layer CL1 may include a barrier layer BRL, a first shielding electrode SE1, a buffer layer BFL, a first semiconductor pattern SCP1, an insulating layer IL10, and a first gate electrode G1.

The first shielding electrode SE1 may be disposed on the base layer BL. The first shielding electrode SE1 may block an influence of electrical potential caused by a polarization phenomenon on the first semiconductor pattern SCP1. Although the first shielding electrode SE1 may include copper (Cu), aluminum (Al), or silver (Ag), embodiments of the present disclosure are not limited thereto.

The barrier layer BRL is disposed on the base layer BL and covers the first shielding electrode SE1. The barrier layer BRL may prevent external foreign substances from being introduced. The barrier layer BRL may include at least one inorganic layer. The barrier layer BRL may include a silicon oxide (SiOₓ) layer and a silicon nitride (SiₓN_{y}) layer. Each of the layers may be provided in plurality, and the silicon oxide (SiOₓ) layers and the silicon nitride (SiₓN_{y}) layers may be alternately laminated on each other.

The buffer layer BFL may be disposed on the barrier layer BRL. The buffer layer BFL may prevent metal atoms or impurities of the base layer BL from being diffused into the first semiconductor pattern SCP1. The buffer layer BFL may include at least one inorganic layer. The buffer layer BFL may include a silicon oxide (SiOₓ) layer and a silicon nitride (SiₓN_{y}) layer.

The first semiconductor pattern SCP1 may be disposed on the buffer layer BFL. The first semiconductor pattern SCP1 may include a first drain region D1, a first active region A1, and a first source region S1.

The insulating layer IL10 may be disposed on the buffer layer BFL and cover the first semiconductor pattern SCP1.

The first gate electrode G1 may be disposed on the insulating layer IL10. In an embodiment of the present disclosure, although not illustrated, the first circuit layer CL1 may be disposed on the same layer as the first gate electrode G1 and may further include signal lines that are insulated from the first gate electrode G1.

However, the embodiment is not limited to the cross-sectional structure and number of layers of the first semiconductor pattern SCP1 and the first gate electrode G1. For example, the cross-sectional structure and number of the layers of the first semiconductor pattern SCP1 and the first gate electrode G1 may be variously modified based on a design of the first circuit layer CL1.

The second circuit layer CL2 may include a first insulating layer IL1, a second insulating layer IL2, a first conductive pattern PT1, and a second conductive pattern PT2.

The first insulating layer IL1 may be disposed on the insulating layer IL10 and cover the first gate electrode G1. The first conductive pattern PT1 and the second conductive pattern PT2 may be disposed on the first insulating layer IL1. The first insulating layer IL1 may insulate the first gate electrode G1 from the first conductive pattern PT1 and from the second conductive pattern PT2.

The first insulating layer IL1 may include a first insulating layer region IL1_a and a second insulating layer region IL1_b.

The first insulating layer region IL1_a may include a region overlapping the first conductive pattern PT1 and have a constant distance from the base layer BL to an upper surface TS1.

The second insulating layer region IL1_b may include a region overlapping the second conductive pattern PT2 and have a constant distance from the base layer BL to an upper surface TS2.

The upper surface TS1 of the first insulating layer region IL1_a may have a first distance L1 from the base layer BL. The upper surface TS2 of the second insulating layer region IL1_b may have a second distance L2 from the base layer BL. Here, the first distance L1 may be greater than the second distance L2.

The first insulating layer IL1 may include a silicon nitride (SiₓN_{y}) layer, a silicon oxynitride (SiOₓN_{y}) layer, a silicon oxide (SiOₓ) layer, a titanium oxide (TiO₂) layer, or an aluminum oxide (Al₂O₃) layer.

The first conductive pattern PT1 may be disposed on the first insulating layer region IL1_a to overlap the first drain region D1. A contact hole CTH1 may be defined in the first insulating layer region IL1_a, overlapping the first conductive pattern PT1. The first conductive pattern PT1 may be electrically connected to the first drain region D1 of the first semiconductor pattern SCP1 through the contact hole CTH1. In an embodiment of the present disclosure, the first conductive pattern PT1 may serve as a drain electrode of a thin-film transistor including the first semiconductor pattern SCP1.

The second conductive pattern PT2 may be disposed on the second insulating layer region IL1_b. The second conductive pattern PT2 may be disposed on the same layer as the first conductive pattern PT1.

The second conductive pattern PT2 may correspond to one of a control line, a signal line, a scan line, a data line, and a power line for driving a single pixel. Although the second conductive pattern PT2 may be connected to a contact hole (not illustrated) defined in the first insulating layer IL1, embodiments of the present disclosure are not limited thereto.

Each of the first conductive pattern PT1 and the second conductive pattern PT2 may include a single layer or a plurality of layers containing at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu). Although the first conductive pattern PT1 and the second conductive pattern PT2 may be formed of the same material, the embodiment not limited thereto. In an example in which the first conductive pattern PT1 and the second conductive pattern PT2 are formed of the same material, the first conductive pattern PT1 and the second conductive pattern PT2 may be provided simultaneously.

In an embodiment of the present disclosure, a thickness C1 of the first conductive pattern PT1 may be substantially equal to a thickness C2 of the second conductive pattern PT2.

The second insulating layer IL2 may cover the second conductive pattern PT2. Here, the second insulating layer IL2 may expose an upper surface of the first conductive pattern PT1. The second insulating layer IL2 may not expose an upper surface of the second conductive pattern PT2.

The upper surface of the second insulating layer IL2 and the upper surface of the first conductive pattern PT1 may be substantially disposed on the same plane as the plane defined by the first direction DR1 and second direction DR2.

The second insulating layer IL2 may include a first portion IL2_a overlapping the first insulating layer region IL1_a and a second portion IL2_b overlapping the second insulating layer region IL1_b.

A thickness T1 of the first portion IL2_a of the second insulating layer IL2 may be substantially equal to the thickness C1 of the first conductive pattern PT1.

A thickness T2 of the second portion IL2_b of the second insulating layer IL2 may be greater than the thickness T1 of the first portion IL2_a.

In an embodiment of the present disclosure, each of the thickness T1 of the first portion IL2_a and the thickness T2 of the second portion IL2_b of the second insulating layer IL2 may represent an average thickness.

The thickness T2 of the second portion IL2_b of the second insulating layer IL2 may be greater than the thickness C2 of the second conductive pattern PT2.

The second insulating layer IL2 may include a silicon nitride (SiₓN_{y}) layer, a silicon oxynitride (SiOₓN_{y}) layer, a silicon oxide (SiOₓ) layer, a titanium oxide (TiO₂) layer, or an aluminum oxide (Al₂O₃) layer.

The second portion IL2_b of the second insulating layer IL2 may cover the second conductive pattern PT2 and prevent electrical short circuit between the second conductive pattern PT2 and conductive patterns above and below the second conductive pattern PT2, which may improve design flexibility of circuit layers and reliability of the display device.

The upper surface of the second insulating layer IL2 may be substantially disposed on the same plane as that defined by the first direction DR1 and second direction DR2. That is, the second insulating layer IL2 may have a flat upper surface. The flat upper surface of the second insulating layer IL2 supports uniform deposition of conductive patterns in a deposition process.

In the display device DP according to an embodiment of the present disclosure, the light-emitting diode layer EL1 may include a first pixel electrode AE1, a first light-emitting layer ED1, and a counter electrode CE. In some aspects, the display device DP may further include a pixel defining layer PDL.

The first pixel electrode AE1 may be disposed on the second insulating layer IL2 and overlap the first conductive pattern PT1. Since the second insulating layer IL2 has a shape that exposes the first conductive pattern PT1, the first conductive pattern PT1 may be in full-surface contact with the first pixel electrode AE1. Accordingly, the first conductive pattern PT1 may be electrically connected to the first pixel electrode AE1 without a contact hole. A structure in which the first conductive pattern PT1 is electrically connected to the first pixel electrode AE1 without a contact hole may increase a contact area and thereby reduce contact resistance. In some aspects, since the first conductive pattern PT1 may be electrically connected to the first pixel electrode AE1 without implementing a process of forming the contact hole in the second insulating layer IL2, a turnaround time (TAT) of an entire process may be reduced. Furthermore, the above-described structure may prevent a defect such as, for example, contact hole blockage, a void, over-etching, a crack, and mismatching and improve the reliability of the display device.

Descriptions of an element being in “full-surface contact” with another element may refer to a state in which an entire surface (e.g., an entire upper surface, an entire lower surface, an entire side surface, or the like) of the element is in contact with the other element.

The pixel defining layer PDL may cover a portion of the first pixel electrode AE1. A first pixel opening PDL_OP1 that exposes a portion of the first pixel electrode AE1 may be defined in the pixel defining layer PDL. A first light-emitting area LEA1 may be defined in correspondence to the first pixel opening PDL_OP1.

In an embodiment of the present disclosure, a hole control layer (not illustrated) may be disposed between the first pixel electrode AE1 and the first light-emitting layer ED1. The hole control layer (not illustrated) may include at least one of a hole transport layer or a hole injection layer. An electron control layer (not illustrated) may be disposed between the first light-emitting layer ED1 and the counter electrode CE. The electron control layer may include at least one of an electron transport layer or an electron injection layer.

The encapsulation layer TFE may be disposed on the light-emitting diode layer EL. The encapsulation TFE may protect the light-emitting diode layer EL from foreign substances such as, for example, moisture, oxygen, and dust particles.

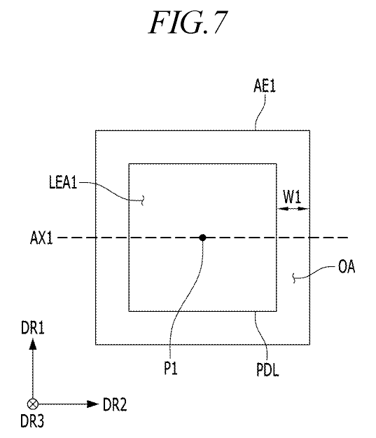

FIG. 7 is a plan view illustrating the first pixel electrode of FIG. 5.

Referring to FIGS. 5 to 7, the first light-emitting area LEA1 may correspond to an area exposed by the first pixel opening PDL_OP1.

Referring to FIG. 5, on a plane, the first pixel electrode AE1 may have a shape that overlaps a portion of the pixel defining layer PDL and covers the first conductive pattern PT1. Although the first pixel electrode AE1 has a rectangular shape in FIG. 5, embodiments of the present disclosure are not limited thereto. For example, the first pixel electrode AE1 may have a polygonal, circular, or elliptical shape.

Referring to FIG. 7, in an embodiment of the present disclosure, a first center P1 may be defined in the first pixel electrode AE1. Here, the first center P1 of the first pixel electrode AE1 may be a geometric center, incenter, circumcenter, excenter, or center of gravity of the first pixel electrode AE1.

The first pixel electrode AE1 may have a symmetrical shape on the plane with respect to a virtual line AX1 passing through the first center P1. In an embodiment, a minimum distance W1 from a boundary of the first light-emitting area LEA1 to a boundary of the first pixel electrode AE1 may be constant on the plane in the first direction DR1 or the second direction DR2.

In an embodiment of the present disclosure, the first pixel electrode AE1 may have a shape similar to that of the first light-emitting area LEA1 on a plane.

Although each of the first pixel electrode AE1 and the first light-emitting area LEA1 has a rectangular shape in FIG. 7, embodiments of the present disclosure are not limited thereto.

In an embodiment of the present disclosure, the first conductive pattern PT1 may be disposed in the first light-emitting area LEA1 on the plane.

In an embodiment of the present disclosure, an overlapping area OA, in which the first pixel electrode AE1 and the pixel defining layer PDL overlap each other on the plane, may be defined.

In another embodiment of the present disclosure, the first conductive pattern PT1 may be disposed in the first pixel electrode AE1 on the plane, while overlapping a portion of the overlapping area OA.

Although the first pattern PT1 has an area less than the area of the first light-emitting area LEA1 in FIG. 7, embodiments of the present disclosure are not limited thereto. For example, the first pattern PT1 may substantially have the same area as the first light-emitting area LEA1. Furthermore, although the first pattern PT1 has a rectangular shape in the drawings, embodiments of the present disclosure are not limited thereto. For example, the first pattern PT1 may have a polygonal, circular, or elliptical shape.

According to the display device DP described with reference to FIGS. 5 to 7, since the first pixel electrode AE1 and the first conductive pattern PT1 are in full-surface contact with each other, the display device DP may be implemented without a separate contact hole in the second insulating layer IL2. Accordingly, since the light-emitting area in the display area DA (refer to FIG. 3) may be expanded, a light-emission efficiency of the display device may be improved, and a resolution of the display device may be improved by minimizing the surrounding area SA for the contact hole.

FIG. 8 is a cross-sectional view of a display device DP1 according to an embodiment of the present disclosure. Since the display device DP1 described with reference to FIG. 8 is substantially the same as the display device DP described with reference to FIGS. 5 to 7 except for a second circuit layer CL2_1, the second circuit layer CL2_1 will be described in detail, and a description of the remaining components will be omitted.

The second circuit layer CL2_1 may include a first insulating layer IL1_1 and a second insulating layer IL2_1 and further include a third insulating layer IL3_1 and a third conductive pattern PT3.

The third insulating layer IL3_1 may be disposed between the insulating layer IL10 and the first insulating layer IL1_1. The third insulating layer IL3_1 serves to electrically insulate the first gate electrode G1 from the third conductive pattern PT3 that will be described later. The third insulating layer IL3_1 may serve as an interlayer insulating film. The third insulating layer IL3_1 may include silicon nitride (SiₓN_{y}), silicon oxynitride (SiOₓN_{y}), silicon oxide (SiO₂), titanium oxide (TiO₂), or aluminum oxide (Al₂O₃).

Although the third insulating layer IL3_1 has a flat upper surface in FIG. 8, embodiments of the present disclosure are not limited thereto.

The third conductive pattern PT3 may be disposed on the third insulating layer IL3_1 to overlap the first conductive pattern PT1. The third conductive pattern PT3 may correspond to one of a control line, a signal line, a scan line, a data line, and a power line for driving a single pixel.

Although the third conductive pattern PT3 may be connected to a transistor (not illustrated) through a contact hole (not illustrated) provided by the third insulating layer IL3_1, embodiments of the present disclosure are not limited thereto. The third conductive pattern PT3 may include a single layer or a plurality of layers containing at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu).

The first insulating layer IL1_1 may be disposed on the third insulating layer IL3_1 and cover the third conductive pattern PT3.

In an embodiment of the present disclosure, the first insulating layer IL1_1 may substantially have a uniform thickness.

Since the first insulating layer IL1_1 has the uniform thickness on the third insulating layer IL3_1 on which the third conductive pattern PT3 is provided, an upper surface of the first insulating layer IL1_1 has a relatively great distance from the base layer BL in an area overlapping the third conductive pattern PT3 and a relatively small distance from the base layer BL in an area that is not overlapping with the third conductive pattern PT3.

The first conductive pattern PT1 may overlap the first drain region D1 and the third conductive pattern PT3. A contact hole (not illustrated) may be provided in an area of the first insulating layer, which overlaps the first conductive pattern PT1. The first conductive pattern PT1 may be electrically connected to the first drain region D1 of the first semiconductor pattern SCP1 through the contact hole (not illustrated). Other descriptions of the first conductive pattern PT1 and the second conductive pattern PT2 are the same as those described with reference to FIGS. 5 to 7.

The second insulating layer IL2_1 may be disposed on the first insulating layer IL1_1. The second insulating layer IL2_1 may expose an upper surface of the first conductive pattern PT1 and cover the second conductive pattern PT2. The second insulating layer IL2_1 may serve to prevent the first conductive pattern PT1 and the second conductive pattern PT2 from being electrically connected to each other.

The display device DP1 according to an embodiment of the present disclosure in FIG. 8 may increase design flexibility of the circuit layer by adding the third conductive pattern PT3. In some aspects, since adding the third conductive pattern PT3 supports an implementation in which the upper surface of the first conductive pattern PT1 is exposed and the first insulating layer IL1_1 substantially maintains the same thickness, a contact area between the first conductive pattern PT1 and the first pixel electrode AE1 may be increased, and contact resistance between the first conductive pattern PT1 and the first pixel electrode AE1 may be reduced.

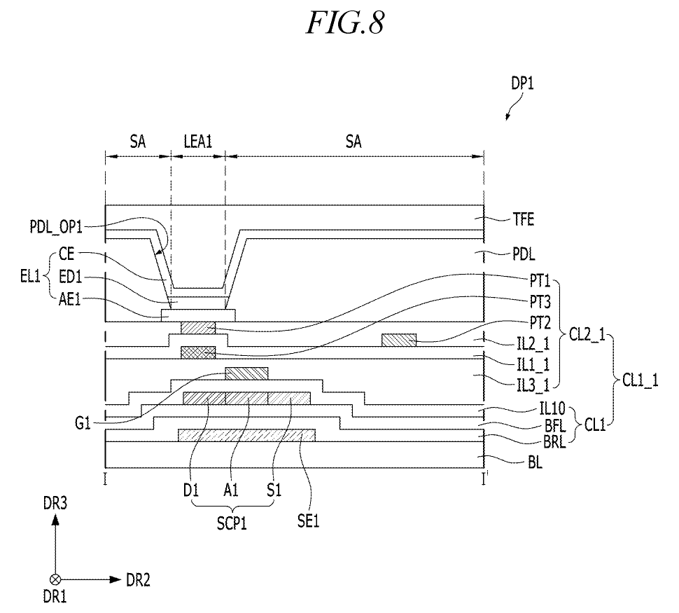

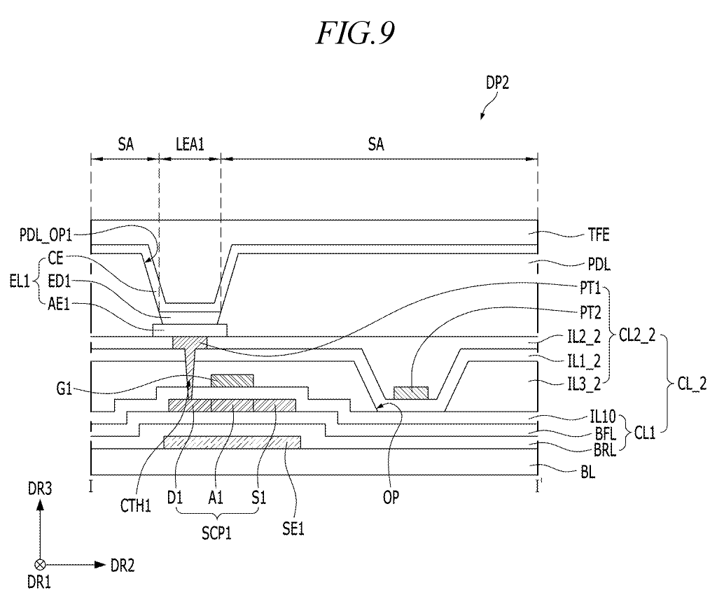

FIG. 9 is a cross-sectional view illustrating a display device DP2 according to an embodiment of the present disclosure.

Since the display device DP2 to be described with reference to FIG. 9 is substantially the same as the display device DP described with reference to FIGS. 5 to 7 except for a second circuit layer CL2_2, the second circuit layer CL2_2 will be described in detail, and a description of the remaining components will be omitted.

The second circuit layer CL2_2 may include a first insulating layer IL1_2 and a second insulating layer IL2_2 and further include a third insulating layer IL3_2.

The third insulating layer IL3_2 may be disposed on the insulating layer IL10.

An opening OP overlapping the second conductive pattern PT2 may be defined in the third insulating layer IL3_2.

The first insulating layer IL1_2 may be disposed on the third insulating layer IL3_2 to have a uniform thickness.

The first insulating layer IL1_2 may have different distances from the base layers BL in an area overlapping the first conductive pattern PT1 and an area overlapping the second conductive pattern PT2 by the opening OP defined in the third insulating layer IL3_2.

The first conductive pattern PT1 may be disposed on an upper surface of an area having a relatively great distance from the base layer BL among the areas of the first insulating layer IL1_2. The first conductive pattern PT1 may be electrically connected to the first drain region D1 of the first semiconductor pattern SCP1 through a contact hole CTH1.

The second conductive pattern PT2 may be disposed on an upper surface of an area having a relatively small distance from the base layer BL among the areas of the first insulating layer IL1_2.

Except for the above-described feature, descriptions of the first conductive pattern PT1 and the second conductive pattern PT2 are the same as those described with reference to FIGS. 5 to 7.

The second insulating layer IL2_2 may be disposed on the first insulating layer IL1_2 and expose the first conductive pattern PT1 and cover the second conductive pattern PT2.

Referring to FIG. 9, in the display device DP2, the opening OP defined in the third insulating layer IL3_2 may provide a difference between heights of the first conductive pattern PT1 and the second conductive pattern PT2. Accordingly, as the upper surface of the first conductive pattern PT1 is exposed while the second conductive pattern PT2 is not exposed, a contact area between the first conductive pattern PT1 and the first pixel electrode AE1 may be increased, and contact resistance between the first conductive pattern PT1 and the first pixel electrode AE1 may be reduced.

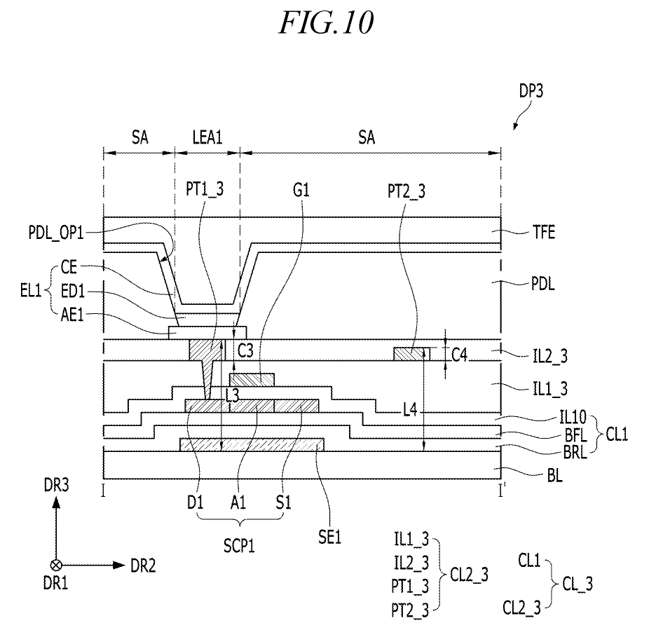

FIG. 10 is a cross-sectional view illustrating a display device DP3 according to an embodiment of the present disclosure. Since the display device DP2 to be described with reference to FIG. 10 is substantially the same as the display device DP described with reference to FIGS. 5 to 7 except for a second circuit layer CL2_3, the second circuit layer CL2_3 will be described in detail, and a description of the remaining components will be omitted.

The second circuit layer CL2_3 may include a first insulating layer IL1_3, a second insulating layer IL2_3, a first conductive pattern PT1_3, and a second conductive pattern PT2_3.

The first insulating layer IL1_3 may be disposed on the insulating layer IL10 while covering the first gate electrode G1. The first insulating layer IL1_3 may have a flat upper surface.

The first conductive pattern PT1_3 may have a thickness C3 greater than a thickness C4 of the second conductive pattern PT2_3. The first conductive pattern PT1_3 and the second conductive pattern PT2_3 may be disposed on the first insulating layer IL1_3 and disposed on the same layer. (FIG. 10 IL1_3 and IL2_3 are exchanged in location. I think) A distance L3 from the first conductive pattern PT1_3 to the substrate may be substantially equal to a distance L4 from the second conductive pattern PT2_3 to the substrate.

The first conductive pattern PT1_3 and the second conductive pattern PT2_3 may be formed of different materials from each other. The first conductive pattern PT1_3 and the second conductive pattern PT2_3 may be provided in different processes. However, embodiments of the present disclosure are not limited thereto. For example, the number of layers included in the first conductive pattern PT1_3 (i.e., the number of layers for forming the first conductive pattern PT1_3) may be different from the number of layers included in the second conductive pattern PT2_3 (i.e., the number of layers for forming the second conductive pattern PT2_3). In an example, the number of layers included in the first conductive pattern PT1_3 may be greater than the number of layers included in the second conductive pattern PT2_3.

The second insulating layer IL2_3 may be disposed on the first insulating layer IL1_3. The second insulating layer IL2_3 may cover the second conductive pattern PT2_3 while exposing the first conductive pattern PT1_3. The second insulating layer IL2_3 may have a substantially uniform thickness in an entire region.

In the display device DP3 described with reference to FIG. 10 according to an embodiment of the present disclosure, the first conductive pattern

PT1_3 may be exposed by the second insulating layer IL2_3 and be brought into full-surface contact with the first pixel electrode AE1 to improve contact resistance between the first conductive pattern PT1_3 and the first pixel electrode AE1. In some aspects, as the first conductive pattern PT1_3 and the second conductive pattern PT2_3 have different thicknesses, the first conductive pattern PT1_3 may be electrically connected to the first pixel electrode AE1, while the second conductive pattern PT2_3 is insulated therefrom, to improve a flexibility in circuit design.

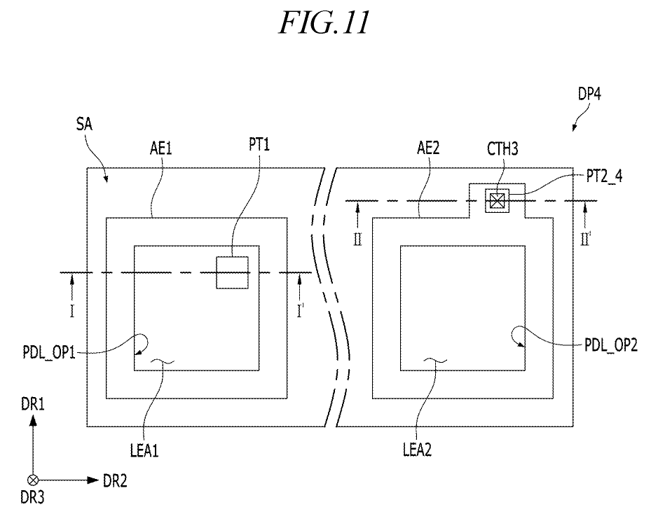

FIG. 11 is a plan view illustrating a display device DP4 according to an embodiment of the present disclosure. FIG. 12 is a cross-sectional view taken along line I-I' and line II-II' of FIG. 11.

Referring to FIGS. 11 and 12, the display device DP4 according to an embodiment of the present disclosure may include a base layer BL, a circuit layer CL, a light-emitting diode layer EL1 or EL2, and an encapsulation layer TFE.

The base layer BL is substantially the same as the base layer BL described with reference to FIGS. 5 to 7.

The circuit layer CL may include a first circuit layer CL1_4 and a second circuit layer CL2_4.

The first circuit layer CL1_4 may include a barrier layer BRL, a buffer layer BFL, a first shielding electrode SE1, a second shielding electrode SE2, a first semiconductor pattern SCP1, a second semiconductor pattern SCP2, an insulating layer IL10, a first gate electrode G1, and a second gate electrode G2.

The barrier layer BRL, the buffer layer BFL, the first shielding electrode SE1, the first semiconductor pattern SCP1, and the first gate electrode G1 are substantially the same as the barrier layer BRL, the buffer layer BFL, the first shielding electrode SE1, the first semiconductor pattern SCP1, and the first gate electrode G1 of the display device DP described with reference to FIGS. 5 to 7. Thus, the second shielding electrode SE2, the second semiconductor pattern SCP2, and the second gate electrode G2 will be described herein.

The second shielding electrode SE2 may be spaced apart from the first shielding electrode SE1 on the same layer, i.e., on the base layer BL. The second shielding electrode SE2 may block an influence of electrical potential caused by a polarization phenomenon on the second semiconductor pattern SCP2. Although the second shielding electrode SE2 may be formed of the same material as the first shielding electrode SE1, embodiments of the present disclosure are not limited thereto.

The second semiconductor pattern SCP2 may be spaced apart from the first semiconductor pattern SCP1 on the same layer, i.e., on the buffer layer BFL. The second semiconductor pattern SCP2 may include a second drain region D2, a second active region A2, and a second source region S2.

The insulating layer IL10 may be disposed on the buffer layer BFL and cover the first semiconductor pattern SCP1 and the second semiconductor pattern SCP2.

The second gate electrode G2 may be spaced apart from the first gate electrode G1 on the same layer, i.e., on the insulating layer IL10. Although not illustrated, in an embodiment of the present disclosure, the first circuit layer CL1_4 may be disposed on the same layer as the first gate electrode G1 and the second gate electrode G2 and further include signal wires insulated from the first gate electrode G1 and the second gate electrode G2.

The embodiment is not limited to the cross-sectional structure and number of layers of the first semiconductor pattern SCP1, the second semiconductor pattern SCP2, the first gate electrode G1, and the second gate electrode G2. For example, the cross-sectional structure and number of layers of the first semiconductor pattern SCP1, the second semiconductor pattern SCP2, the first gate electrode G1, and the second gate electrode G2 may be variously modified based on a design of the first circuit layer CL1_4.

The second circuit layer CL2_4 may include a first insulating layer IL1_4, a second insulating layer IL2_4, a first conductive pattern PT1, and a second conductive pattern PT2_4.

The first insulating layer IL1_4 may be disposed on the insulating layer IL10 and cover the first gate electrode G1 and the second gate electrode G2. The first conductive pattern PT1 and the second conductive pattern PT2_4 may be disposed on the first insulating layer IL1_4. The first insulating layer IL1 may insulate the first gate electrode G1 from the first conductive pattern PT1 and from the second conductive pattern PT2_4.

Since the first conductive pattern PT1 is substantially the same as the first conductive pattern PT1 of the display device DP described with reference to FIGS. 5 to 7 according to an embodiment of the present disclosure, the first insulating layer IL1_4 and the second conductive pattern PT2_4 will be mainly described herein.

The second conductive pattern PT2_4 may be disposed on the first insulating layer IL1_4 to overlap the second drain region D2. A contact hole CTH3 may be defined in a portion of the first insulating layer IL1_4, which overlaps the second conductive pattern PT2_4. The second conductive pattern PT2_4 may be electrically connected to the second drain region D2 of the second semiconductor pattern SCP2 through a contact hole CTH2. In an embodiment of the present disclosure, the second conductive pattern PT2_4 may serve as a drain electrode of a thin-film transistor including the second semiconductor pattern SCP2.

The second insulating layer IL2_4 may cover the second conductive pattern PT2_4. Here, the second insulating layer IL2_4 may expose an upper surface of the first conductive pattern PT1. The second insulating layer IL2_4 may not expose an upper surface of the second conductive pattern PT2_4. A contact hole CTH3 may be defined in the second insulating layer IL2_4 to overlap the second conductive pattern PT2_4 and a second pixel electrode AE2 that will be described later.

A display device DP4 according to an embodiment of the present disclosure may further include a second light-emitting diode layer EL2 in comparison with the display device DP described with reference to FIGS. 5 to 7 according to an embodiment of the present disclosure.

The second light-emitting diode layer EL2 may include a second pixel electrode AE2, a second light-emitting layer ED2, and a counter electrode CE.

The second pixel electrode AE2 may be spaced apart from the first pixel electrode AE1 on the second insulating layer IL2. The second pixel electrode AE2 may be disposed on the same layer as the first pixel electrode AE1. The second pixel electrode AE2 may overlap the second conductive pattern PT2_4. The second pixel electrode AE2 may be electrically connected to the second conductive pattern PT2_4 through the contact hole CTH3.

A pixel defining layer PDL may cover one portion of the first pixel electrode AE1 and one portion of the second pixel electrode AE2. In the pixel defining layer PDL, a first pixel opening PDL_OP1 that exposes the other portion of the first pixel electrode AE1 and a second pixel opening PDL_OP2 that exposes the other portion of the second pixel electrode AE2 may be defined. In an embodiment of the present disclosure, a first light-emitting area LEA1 may be defined in correspondence to the first pixel opening PDL_OP1, and a second light-emitting area LEA2 may be defined in correspondence to the second pixel opening PDL_OP2.

Since the first light-emitting area LEA1 is the same as the first light-emitting area LEA1 of the display device DP described with reference to FIGS. 5 to 7, the second light-emitting area LEA2 will be mainly described herein.

Referring to FIG. 11, on the plane, the second pixel electrode AE2 may have a shape that overlaps a portion of the pixel defining layer PDL and covers the second conductive pattern PT2_4. The second conductive pattern PT2_4 may overlap with the pixel defining layer PDL in a planar view but may not overlap with the second light-emitting area LEA2. The contact hole CTH3 may overlap with both the pixel defining layer PDL and the second conductive pattern PT2_4 in a planar view.

On the plane, the second conductive pattern PT2_4 may be disposed outside the second light-emitting area LEA2 instead of being disposed in the second light-emitting area LEA2. In comparison, since the first conductive pattern PT1 is in full-surface contact with the first pixel electrode AE1 without a contact hole, the first conductive pattern PT1 may be disposed in the first light-emitting area LEA1 on the plane.

Since the first pixel electrode AE1 directly contacts the circuit layer in the first light-emitting area LEA1, the first pixel electrode AE1 may be implemented without being dependent on having a shape for contact in the surrounding area SA outside the first light-emitting area LEA1. Thus, the first pixel electrode AE1 may have a shape similar to the shape of the first light-emitting area LEA1 and secure a relatively large area of the first light-emitting area LEA1 occupied in the display area DA (refer to FIG. 1) to improve luminance of the display device. In some aspects, in the display area DA (refer to FIG. 1), resolution of the display device may be improved by reducing a size of the surrounding area SA adjacent to the first light-emitting area LEA1.

The second pixel electrode AE2 may not be in direct contact with the circuit layer in the second light-emitting area LEA2, but have a shape for contact in the surrounding area SA outside the second light-emitting area LEA2.

In an embodiment of the present disclosure, although respective upper surfaces of the first conductive pattern PT1 and the second insulating layer IL2_4 are disposed on the same plane, a process error may exist based on differences between materials and formation processes of the first conductive pattern PT1 and the second insulating layer IL2_4.

In an embodiment of the present disclosure, since the third contact hole CH3 is disposed outside the second light-emitting area LEA2 on the plane, an upper surface of the second insulating layer IL2_4, on which the second pixel electrode AE2 is disposed at a position overlapping the second light-emitting area LEA2, may be relatively more flat than a position overlapping the first light-emitting area LEA1. Thus, the second light-emitting area LEA2 may have improved light emission efficiency of a light-emitting layer or improved external light reflection efficiency in comparison with the first light-emitting area LEA1 to improve optical characteristics of the display device.

For example, since human eyes have relatively low visibility to blue light, a performance of the display device may be improved when more blue light transmits. Thus, in an embodiment of the present disclosure, a blue light-emitting area may have the same structure as the first light-emitting area LEA1 described with reference to FIGS. 11 and 12. In some aspects, since the human eyes have relatively high visibility to green light, the optical characteristics of the display device may be improved by enhancing reflection characteristics of green light. In an embodiment of the present disclosure, a green light-emitting area may have the same structure as the second light-emitting area LEA2 described with reference to FIGS. 11 and 12. A person skilled in the art may appropriately mix the above-described structures to find an optimized combination.

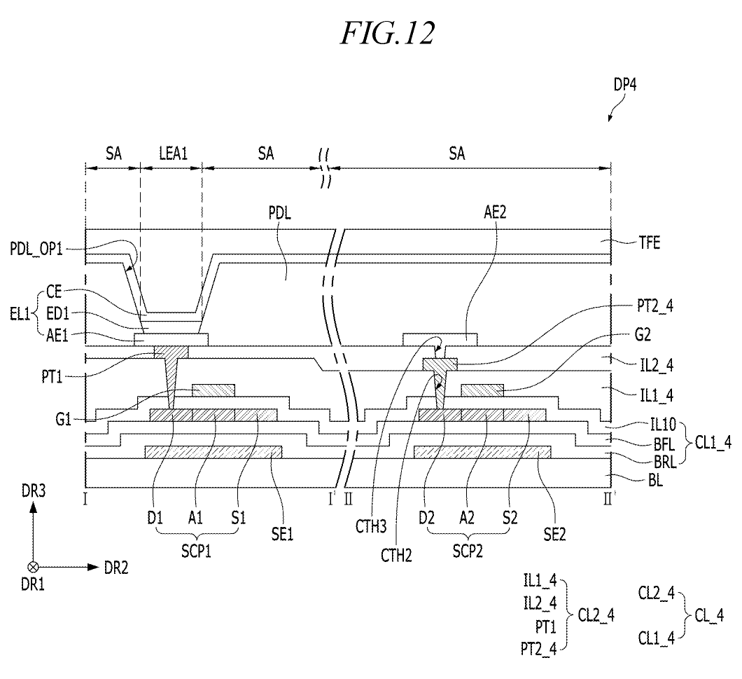

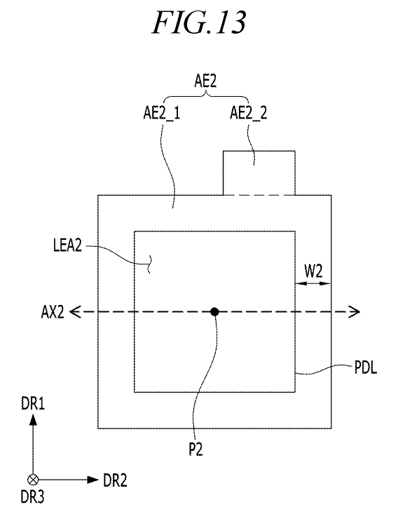

FIG. 13 is a view illustrating the second pixel electrode AE2 on the plane.

Referring to FIG. 13, the second pixel electrode AE2 may have a shape that is not symmetric with respect to any imaginary line AX2 on the plane. In an embodiment, a minimum distance W2 from a boundary of the second light-emitting area LEA2 to a boundary of the second pixel electrode AE2 on the plane may not be constant in the first direction DR1 or the second direction DR2.

The second pixel electrode AE2 may include a base part AE2_1 and a protruding part AE2_2.

On the plane, the second light-emitting area LEA2 may be defined in the base part AE2_1.

In an embodiment of the present disclosure, a second center P2 of the base part AE2_1 may be defined on the plane. Here, the second center P2 may be a geometric center, incenter, circumcenter, or excenter of the second light-emitting area LEA2.

The base part AE2_1 may have a shape similar to that of the second light-emitting area LEA2 on the plane. In some aspects, the base part AE2_1 may have a shape symmetric with respect to an imaginary line AX2 passing through the second center P2 on the plane. Although the base part AE2_1 has a rectangular shape, embodiments of the present disclosure are not limited thereto. For example, the base part AE2_1 may have various shapes.

The protruding part AE2_2 may extend from one side of the base part AE2_1 on the plane. The protruding part AE2_2 may overlap the contact hole CTH3 described with reference to FIGS. 11 and 12. The protruding part AE2_2 may have various shapes. The second pixel electrode AE2 may have an asymmetric shape by the protruding part AE2_2.

In the display device according to an embodiment of the present disclosure, the base part AE2_1 may be disposed on a flat portion of the second insulating layer IL2_4 because the second pixel electrode AE2 has a shape including the protruding part AE2_2 overlapping the contact hole CTH3 (refer to FIG. 11). The second light-emitting area LEA2 may have improved optical characteristics.

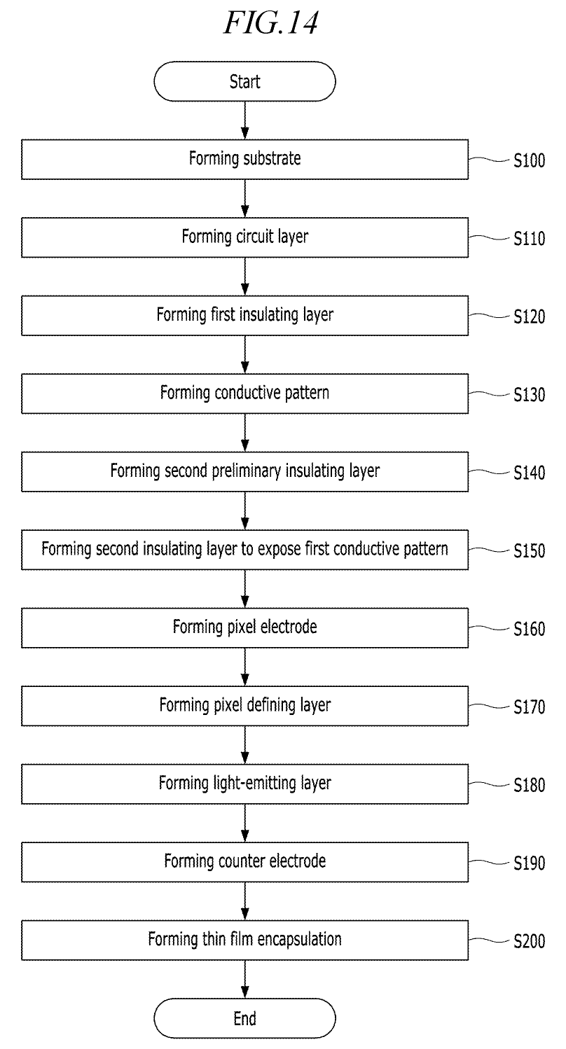

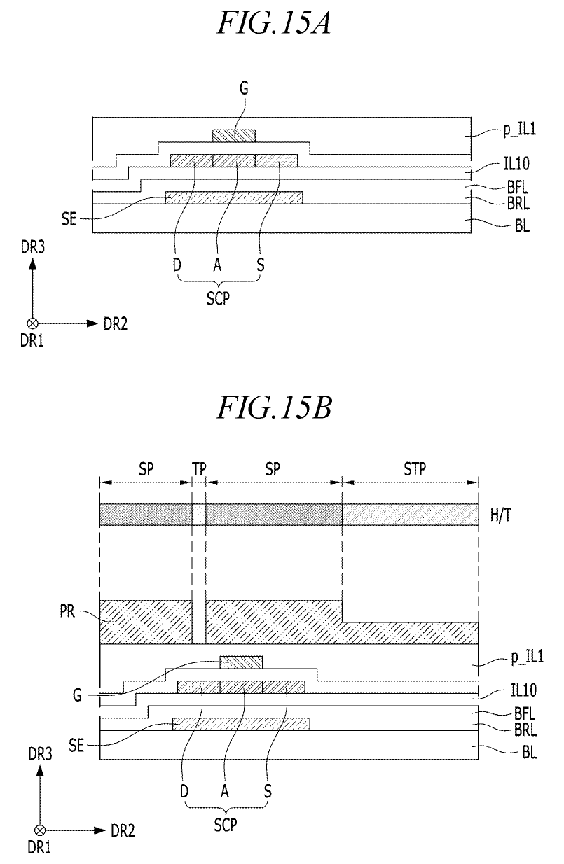

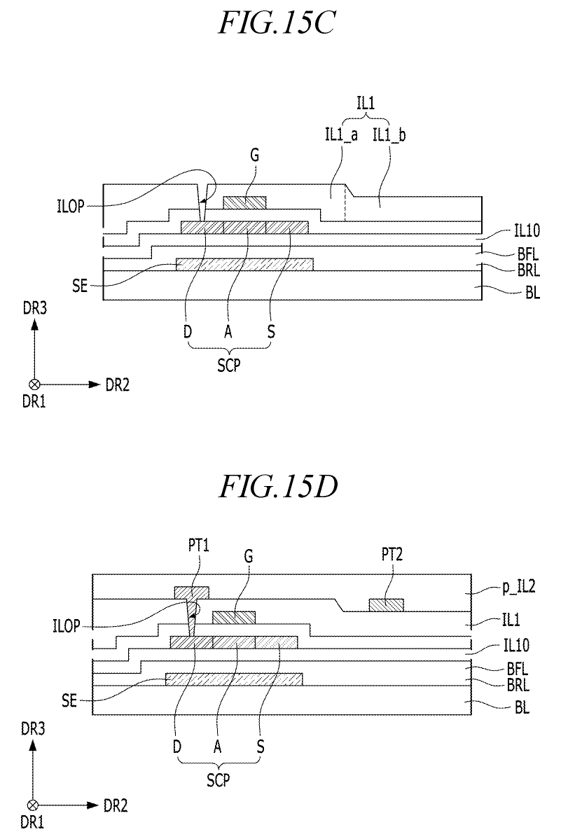

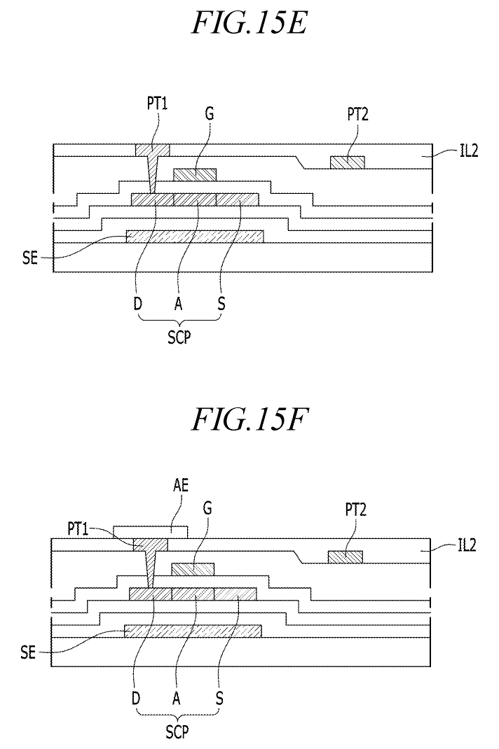

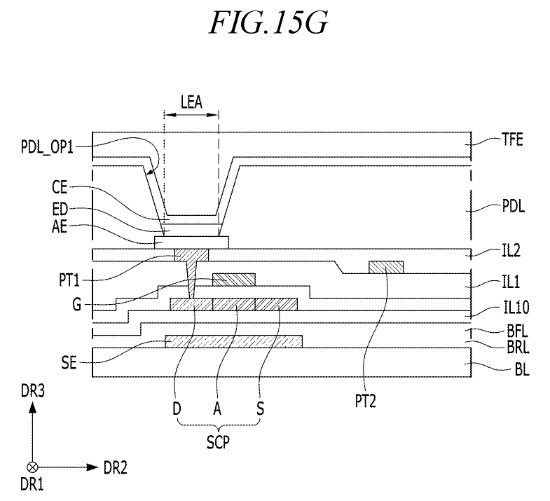

FIG. 14 is a flowchart illustrating a method for manufacturing a display device according to an embodiment of the present disclosure. FIGS. 15A to 15G are schematic views illustrating processes of the method for manufacturing the display device according to an embodiment of the present disclosure.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing the element, forming the element, and the like in accordance with example aspects described herein.

Hereinafter, the method for manufacturing the display device according to an embodiment will be described with reference to FIGS. 14 to 15G. Here, the same components as those described previously will be designated by the same reference numerals are used, and a detailed description thereof will be omitted.

Referring to FIG. 14, the method for manufacturing the display device according to an embodiment may include: forming a substrate S100; forming a circuit layer S110; forming a first insulating layer S120; forming a conductive pattern S130; forming a second preliminary insulating layer S140; forming a second insulating layer which exposes a first conductive pattern S150; forming a first pixel electrode S160; forming a pixel defining layer S170; forming a light-emitting layer S180; forming a counter electrode S190; and forming an encapsulation layer S200.

Referring to FIGS. 14 and 15A, a base layer BL may be prepared in forming the substrate S120.

Referring to FIGS. 14 and 15A, in the process S110 of forming the circuit layer, a shielding electrode SE, a barrier layer BRL, a buffer layer BFL, a semiconductor pattern SCP, an insulating layer IL10, a gate electrode G, and a first preliminary insulating layer p_IL1 may be sequentially formed on the base layer BL. Here, the shielding electrode SE, the semiconductor pattern SCP, and the gate electrode G may be patterned through a photolithography process.

Referring to FIGS. 14, 15B, and 15C, a photoresist material is applied onto the first preliminary insulating layer p_IL1. Thereafter, a photoresist PR may be formed by using a halftone mask H/T (refer to FIG. 15B).

Although an example of using a positive photoresist, in which an exposed portion is removed, is described in an embodiment of the present disclosure, embodiments of the present disclosure are not limited thereto. For example, a negative photoresist, in which an unexposed portion is removed, may be used.

The halftone mask H/T may include a transparent part TP, a semi-transparent part STP, and a shielding part SP.

The photoresist PR may have different thicknesses corresponding to respective areas of the halftone mask H/T.

Referring to FIGS. 15B and 15C, the first preliminary insulating layer p_IL1 may be formed into a first insulating layer IL1 including a plurality of areas having different heights of upper surfaces by using the photoresist PR as a mask.

The first insulating layer IL1 may include a first insulating layer region IL1_a and a second insulating layer region IL1_b. The first insulating layer area Il1_a corresponding to the shielding part SP of the halftone mask H/T may have a relatively great height. The second insulating layer region IL1_b corresponding to

the semi-transparent part STP of the halftone mask H/T may have a relatively low height. In some aspects, an insulating layer opening ILOP may be formed in the first insulating layer IL1 at a position corresponding to the transparent part TP of the halftone mask H/T.

Referring to FIGS. 14 and 15D, a first conductive pattern PT1 and a second conductive pattern PT2 may be formed in the process S130 of forming the conductive pattern.

The first conductive pattern PT1 may be disposed on the first insulating layer area IL1_a to overlap the insulating layer opening ILOP. The first conductive pattern PT1 may be electrically connected to a drain region D of the semiconductor pattern SCP through the insulating layer opening ILOP.

The second conductive pattern PT2 may be disposed on the second insulating layer area IL1_b.

Although the first conductive pattern PT1 and the second conductive pattern PT2 may be formed of the same material simultaneously, embodiments of the present disclosure are not limited thereto. For example, the first conductive pattern PT1 and the second conductive pattern PT2 may be formed of different materials in different processes. Furthermore, the first conductive pattern PT1 and the second conductive pattern PT2 may have different thicknesses.

In the process S140 of forming the second preliminary insulating layer, a second preliminary insulating layer p_IL2 may be formed on the first insulating layer IL1. The second preliminary insulating layer p_IL2 may cover the first conductive pattern PT1 and the second conductive pattern PT2.

Referring to FIGS. 14, 15D, and 15E, in the process S150 of forming the second insulating layer which exposes the first conductive pattern, the second insulating layer IL2 may be formed by chemically or physically polishing an upper surface of the second preliminary insulating layer p_IL2.

The second preliminary insulating layer p_IL2 may be polished such that an upper surface of the second insulating layer IL2 and an upper surface of the first conductive pattern PT1 are formed on the same plane. Accordingly, the second insulating layer IL2 may be formed and expose the upper surface of the first conductive pattern PT1. The second preliminary insulating layer p_IL2 may be polished such that the first conductive pattern PT1 is exposed through the second insulating layer IL2, while the second conductive pattern PT2 is not exposed.

Referring to FIGS. 14 and 15F, in the process S160 of forming the pixel electrode, a pixel electrode AE may be patterned on the second insulating layer IL2 such that the pixel electrode AE is in full-surface contact with the upper surface of the first conductive pattern PT1. Thus, since the pixel electrode AE is in full-surface contact with the upper surface of the first conductive pattern PT1, the display device may be manufactured by the method without forming a separate contact hole for electrical connection in the second insulating layer IL2.

Referring to FIGS. 14 and 15G, in the process S170 of forming the pixel defining layer, a pixel defining layer PDL may be formed on the second insulating layer IL2. A pixel opening PDL_OP that exposes a portion of the pixel electrode AE may be formed in the pixel defining layer PDL.

In the process S180 of forming the light-emitting layer, a light-emitting layer ED may be formed on the pixel electrode AE to overlap the light-emitting area LEA corresponding to the pixel opening PDL_OP.

In the process S190 of forming the counter electrode, a counter electrode CE may be formed on the pixel defining layer PDL and the light-emitting layer ED.

In the process S200 of forming the encapsulation layer, the method may include forming a thin film encapsulation TFE on the second insulating layer IL2. The thin film encapsulation TFE may cover the counter electrode CE. Although not illustrated, in the process S200 of forming the encapsulation layer, a plurality of organic layers and a plurality of inorganic layers may be alternately laminated with each other.

The method for manufacturing the display device according to an embodiment of the present disclosure may chemically and physically polish the second preliminary insulating layer p_IL2 such that the second insulating layer IL2 exposes the first conductive pattern PT1. Thus, since the method may be implemented without performing an additional process for forming a contact hole to electrically connect the pixel electrode AE and the first conductive pattern, a process efficiency may be improved. In some aspects, since the first conductive pattern PT1 formed from a single conductive layer is exposed through the second insulating layer IL2, while the second conductive pattern PT2 is not exposed through the second insulating layer IL2, a flexibility in circuit design may be improved.

The first conductive pattern and the first pixel electrode of the display device according to embodiments of the present disclosure may be electrically connected through the full-surface contact therebetween. This increases the contact area between the first conductive pattern and the first pixel electrode, which may reduce the contact resistance. Thus, since the display device according to embodiments of the present disclosure may be implemented without the contact hole, the turnaround time (TAT) of the entire process may be reduced. In some aspects, the defects such as, for example, contact hole blockage, voids, over-etching, cracks, and mismatching may be prevented in advance. As a result, the display device with the improved reliability may be provided.

In the display device according to embodiments of the present disclosure, the second conductive pattern is not exposed through the upper surface of the second insulating layer. As a result, this may prevent electrical short-circuits between the second conductive pattern and conductive patterns disposed above and below the second conductive pattern, which may increase the flexibility of circuit design and improve the reliability of the display device.

Since the display device according to embodiments of the present disclosure may increase the light-emitting area through the full-surface contact between the first conductive pattern and the first pixel electrode, the light-emitting efficiency of the display device may be improved. In some aspects, the resolution of the display device can be improved by minimizing the total area for implementing each contact hole (i.e., size of each contact hole). As a result, the display device with improved display quality may be provided.

Although the example embodiments of the present invention have been described, it is understood that the present invention should not be limited to these example embodiments but various changes and modifications can be made by one ordinary skilled in the art within the spirit and scope of the present invention as hereinafter claimed.

What is claimed is:

1. A display device comprising:
a substrate;
a circuit layer disposed on the substrate;
a first insulating layer disposed on the circuit layer;
a first conductive pattern disposed on the first insulating layer;
a second insulating layer disposed on the first insulating layer and which exposes an upper surface of the first conductive pattern; and
a first pixel electrode disposed on the second insulating layer,
wherein:
the upper surface of the first conductive pattern is in full-surface contact with the first pixel electrode, and
the upper surface of the first conductive pattern and an upper surface of the second insulating layer are disposed on the same plane.

2. The display device of claim 1, further comprising a second conductive pattern disposed on the first insulating layer,
wherein a distance between the substrate and the first conductive pattern is greater than a distance between the substrate and the second conductive pattern.

3. The display device of claim 2, wherein:
the second insulating layer covers the second conductive pattern, and
the upper surface of the second insulating layer is flat.

4. The display device of claim 2, wherein the first insulating layer comprises:
a first insulating layer region which has a flat upper surface and on which the first conductive pattern is disposed; and
a second insulating layer region which has a flat upper surface and on which the second conductive pattern is disposed,
wherein the first insulating layer region has a thickness greater than a thickness of the second insulating layer region.

5. The display device of claim 2, wherein the circuit layer comprises:
a third insulating layer disposed below the first insulating layer; and
a third conductive pattern disposed between the first insulating layer and the third insulating layer,
wherein:
the third conductive pattern overlaps the first conductive pattern, and
the first insulating layer has a substantially uniform thickness.

6. The display device of claim 2, wherein:
the circuit layer comprises a third insulating layer disposed below the first insulating layer,
a contact hole that overlaps the second conductive pattern is defined in the third insulating layer, and
the first insulating layer has a substantially uniform thickness.

7. The display device of claim 1, further comprising a second conductive pattern disposed on the first insulating layer,
wherein:
the first conductive pattern has a thickness greater than a thickness of the second conductive pattern,
the second insulating layer covers the second conductive pattern, and
the upper surface of the second insulating layer is flat.

8. The display device of claim 7, wherein a number of layers of the first conductive pattern is greater than a number of layers of the second conductive pattern.

9. The display device of claim 1, further comprising a pixel defining layer which is disposed on the second insulating layer and the first pixel electrode and in which a first pixel opening which exposes a portion of the first pixel electrode is defined,
wherein the first pixel opening overlaps the first conductive pattern on a plane.

10. The display device of claim 9, wherein the first pixel electrode has a symmetrical shape with respect to a virtual line passing through a center of the first pixel electrode on the plane.

11. The display device of claim 1, further comprising:
a second pixel electrode spaced apart from the first pixel electrode; and
a second conductive pattern disposed on the first insulating layer and connected to the second pixel electrode through a contact hole defined in the second insulating layer.

12. The display device of claim 11, wherein a distance between the substrate and the first conductive pattern is greater than a distance between the substrate and the second conductive pattern.

13. The display device of claim 11, further comprising a pixel defining layer which is disposed on the second insulating layer, the first pixel electrode, and the second pixel electrode and in which a first pixel opening which exposes a portion of the first pixel electrode and a second pixel opening which exposes a portion of the second pixel electrode are defined,
wherein:
the first pixel opening overlaps the first conductive pattern on a plane, and
the second pixel opening overlaps the second conductive pattern on the plane.

14. The display device of claim 13, wherein:
the first pixel electrode has a symmetrical shape with respect to a virtual line passing through a center of the first pixel electrode on the plane, and
the second pixel electrode has a symmetrical shape with respect to a virtual line passing through a center of second pixel electrode on the plane.

15. A method for manufacturing a display device, the method comprising:
forming a substrate;
forming a circuit layer on the substrate;
forming a first insulating layer on the circuit layer;
forming a conductive layer, wherein the forming of the conductive layer forms a first conductive pattern on the first insulating layer;
forming a second preliminary insulating layer on the first insulating layer, wherein the second preliminary insulating layer covers the first conductive pattern;
forming a second insulating layer by polishing the second preliminary insulating layer, wherein the second insulating layer exposes an entire upper surface of the first conductive pattern; and
forming a first pixel electrode on the first conductive pattern and the second insulating layer, wherein the first pixel electrode is in full-surface contact with the upper surface of the first conductive pattern.

16. The method of claim 15, wherein:
the forming of the conductive layer forms a second conductive pattern spaced apart from the first conductive pattern, and
the forming of the first insulating layer comprises:
forming a first preliminary insulating layer on the circuit layer; and
patterning the first preliminary insulating layer by using a halftone mask,
wherein:
the first insulating layer comprises a first insulating layer region that overlaps the first conductive pattern and has a flat upper surface and a second insulating layer region that overlaps the second conductive pattern and has a flat upper surface, and
the first insulating layer region has a thickness greater than a thickness of the second insulating layer region.

17. The display device of claim 1, further comprising:
a first transistor disposed on the substrate, wherein the first transistor is connected to the first pixel electrode; and
a pixel defining layer which is disposed on the first transistor and the first pixel electrode and in which a first pixel opening which exposes a portion of the first pixel electrode is defined,
wherein the first pixel electrode has a symmetrical shape with respect to a virtual line passing through a center of the first pixel electrode on a plane.

18. The display device of claim 17, wherein the first pixel opening overlaps the first conductive pattern.

19. The display device of claim 17, further comprising:
a second transistor disposed on the substrate and spaced apart from the first transistor; and
a second pixel electrode connected to the second transistor,
wherein:
a second pixel opening which exposes a portion of the second pixel electrode is defined in the pixel defining layer, and
the second pixel electrode has an asymmetrical shape with respect to a virtual line passing through a center of the second pixel electrode on the plane.

20. An electronic device comprising:
a processor which controls a display device;
a memory which stores data for operating the display device or the processor; and
a power conversion module which generates or supplies power,
wherein the display device comprises:
a substrate;
a circuit layer disposed on the substrate;
a first insulating layer disposed on the circuit layer;
a first conductive pattern disposed on the first insulating layer;
a second insulating layer disposed on the first insulating layer and which exposes an upper surface of the first conductive pattern; and
a first pixel electrode disposed on the second insulating layer,
wherein:
the upper surface of the first conductive pattern is in full-surface contact with the first pixel electrode, and
the upper surface of the first conductive pattern and an upper surface of the second insulating layer are disposed on the same plane.
